(19) United States
(12) Patent Application Publication
(10) Pub. No.: US 2025/0185170 A1
(43) Pub. Date: Jun. 5, 2025

(54) Component with one or more electrically conductive patterns for an electrical, radio or electronic device, and device comprising such a component

(71) Applicant: JET METAL TECHNOLOGIES, CHAMPAGNE-AU-MONT-D'OR (FR)

(72) Inventors: Samuel Paul Henry STREMSDOERFER, COLLONGES AU MONT D'OR (FR); Pierrick Guillaume Thierry PLANTEVIN, CAIRANNE (FR)

(21) Appl. No.: 18/842,947

(22) PCT Filed: Mar. 3, 2023
(86) PCT No.: PCT/FR2023/050291

§ 371 Date: Aug. 30, 2024

(30) Foreign Application Priority Data
Mar. 4, 2022 (FR) FR2201909

(51) Int. Cl. H05K 1/16; G01R 27/02; G01R 27/26; H01Q 1/38

(52) U.S. Cl. CPC H05K 1/16; G01R 27/02; G01R 27/2605; H01Q 1/38; H05K 2201/10151

(57) ABSTRACT

The invention relates to a component (1) for an electrical, radio or electronic device, comprising a substrate (3) provided with a dielectric surface (4) carrying at least one electro-conductive pattern (5) that has a lower surface (5A) in contact with the dielectric surface (4) and an opposite upper surface (5B), said electro-conductive pattern being made of metal, the upper surface of the electro-conductive pattern having a roughness Sa less than or equal to 500 nm, said electro-conductive pattern having a thickness (e) of between 10 nm and 500 nm and a sheet resistance that is less than or equal to 800 mΩ/□. The invention further relates to an electrical, radio or electronic device comprising such a component.

Components with electro-conductive patterns; electrical, radio or electronic devices comprising components with electro-conductive patterns.

### TECHNICAL FIELD

The present invention relates to the general technical field of components for electrical, radio or electronic devices, such as in particular for radio frequency transmitter and/or receiver radio devices or for sensors/detectors, comprising a substrate provided with a dielectric surface carrying at least one electro-conductive pattern.

The invention more particularly relates to a component for an electrical, radio or electronic device, comprising a substrate provided with a dielectric surface carrying at least one electro-conductive pattern, said electro-conductive pattern having a lower surface in contact with said dielectric surface and an opposite upper surface. The invention also relates to an electrical, radio or electronic device comprising such a component.

### PRIOR ART

In the field of components for electrical, radio or electronic devices with electro-conductive pattern(s), components manufactured by so-called “printed electronics” techniques, which consist in making electro-conductive patterns on the surface of a substrate by printing (by means, for example, of an inkjet technique or a screen printing technique) using a conductive ink or paste, are known for some years. These conductive inks or pastes typically comprise a polymeric liquid or paste phase, in which are dispersed particles of an electro-conductive material. After printing, the deposited ink or paste is subjected to a drying/curing step to thus form electro-conductive patterns with a polymer matrix in which are caught the particles of electro-conductive material that provide their electro-conductive nature to the patterns formed.

Among the devices integrating such a component, radio frequency antennas are known, in particular, such as for example RFID tags, the antenna radiating element of which is formed by an electro-conductive pattern printed on a dielectric substrate in accordance with the above. Although such known devices and components are generally satisfying, there is still room for improvement in terms of controlling electrical conductivity properties of their printed electro-conductive patterns, and hence, in terms of radio performance level, and that in particular for applications in radio frequency ranges from ultra-high frequencies (UHF) to Terahertz frequencies (THz).

Moreover, the known devices and components sometimes lack reliability and durability, the properties of their printed electro-conductive patterns tend to degrade over time, under the effect of ageing of the polymer matrix of the patterns, migration of the particles of electro-conductive material, etc. This may cause in particular an undesirable variation of the properties of the electro-conductive patterns as a function of environmental variables (humidity, temperature, etc.). Moreover, while the introduction of printed electronics techniques has led to advances in terms of lower manufacturing costs, reduced weight and easier integration of components, there is still much progress to be made in this area. In particular, the conductive inks used are still generally relatively expensive, and the patterns must be printed in relatively large thicknesses to obtain a sufficient electric conductivity.

### DISCLOSURE OF THE INVENTION

The objects assigned to the invention therefore aim to provide a response to the above-mentioned needs and issues, and to propose in particular a new component with electro-conductive pattern(s) for an electrical, radio or electronic device, the electro-conductive pattern(s) of which have excellent electrical properties, suitable in particular for manufacturing radio devices operating at very high radio frequencies or for electronic devices such as sensors.

Another object of the invention aims to propose a new component for an electrical, radio or electronic device that, while having excellent electrical properties, is particularly space-saving and easy to integrate.

Another object of the invention aims to propose a new component for an electrical, radio or electronic device that, while having excellent electrical properties, is particularly inexpensive to manufacture.

Another object of the invention aims to propose a new component for an electrical, radio or electronic device that, while having excellent electrical properties, is particularly durable and reliable.

Another object of the invention aims to propose a new electrical, radio or electronic device comprising a component with electro-conductive pattern(s), the electrical, radio or electronic operation of which is particularly efficient.

Another object of the invention aims to propose a new electrical, radio or electronic device comprising a component with electro-conductive pattern(s) that is space-saving and easy to integrate.

Another object of the invention aims to propose a new electrical, radio or electronic device comprising a component with electro-conductive pattern(s) that is inexpensive to manufacture.

Another object of the invention aims to propose a new electrical, radio or electronic device comprising a component with electro-conductive pattern(s) that is durable and reliable.

Another object of the invention aims to propose a new radio device, such as a radio frequency transmitter and/or receiver device, whose radio frequency antenna radiating element has a particularly high quality factor and radiation efficiency.

Another object of the invention aims to propose a new electronic device forming a sensor/detector having an excellent measurement resolution.

The objects assigned to the invention are achieved using a component for an electrical, radio or electronic device, comprising a substrate provided with a dielectric surface carrying at least one electro-conductive pattern, said electro-conductive pattern having a lower surface in contact with said dielectric surface and an opposite upper surface, said component being characterized in that said electro-conductive pattern is made of metal, the upper surface of the electro-conductive pattern having a roughness Sa less than or equal to 500 nm, said electro-conductive pattern having a thickness of between 10 nm and 500 nm.

The objects assigned to the invention are further achieved by means of an electrical, radio or electronic device comprising such a component.

### BRIEF DESCRIPTION OF THE DRAWINGS

Other features and advantages of the invention will appear in more detail upon reading of the following description, with reference to the appended drawings, given by way of purely illustrative and non-limiting examples, in which:

FIG. 1 schematically illustrates, in a cross-sectional view, an example of component according to the invention;

FIG. 2 schematically illustrates, in a cross-sectional view, another example of component according to the invention;

FIG. 3 illustrates an example of radio device in accordance with the invention, which constitutes a three-dimensional tag for a radio frequency identification (“Radio Frequency IDentification” (RFID)) system, the electro-conductive pattern forming an RFID radio frequency antenna radiating element;

FIG. 4 illustrates an example of component for a radio device according to the invention, whose electro-conductive patterns form a WiFi® dipole radio frequency antenna radiating element;

FIG. 5 illustrates an example of component for an electronic device such as a capacitive sensor, whose electro-conductive patterns form capacitive sensor electrodes;

FIG. 6 illustrates an example of electrical device according to the invention, which constitutes a heating electrical device, forming a heated/de-icing radome for a radio tracking system (proximity radar sensor), the electro-conductive pattern of which forms a heating circuit.

### BEST WAY TO IMPLEMENT THE INVENTION

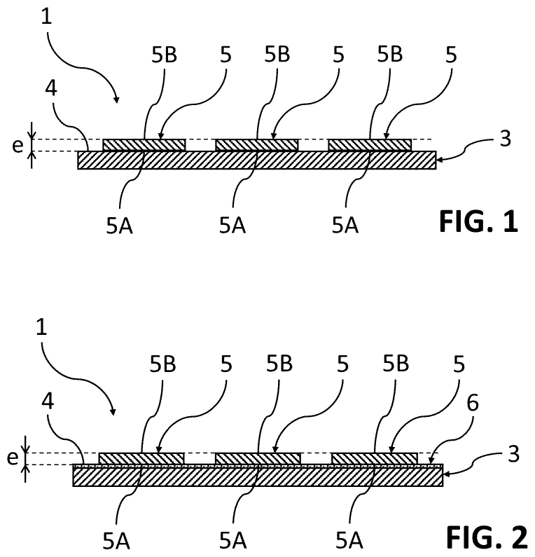

The invention first relates to a component 1 for an electrical, radio or electronic device 2, i.e. a functional element or sub-assembly designed to be integrated into an electrical, radio or electronic device 2 to provide (or at least contribute to provide) therein a particular electrical, radio or electronic function. The component 1 comprises a substrate 3 provided, directly or indirectly, with a dielectric surface 4 carrying at least one electro-conductive pattern 5. Said substrate 3 thus forms a support for said electro-conductive pattern 5. Herein, “dielectric surface” advantageously means a surface that is not electrically conductive, i.e. electrically insulating, and in particular a non-metallic surface. Herein, “electro-conductive pattern” generally means a layer of an electro-conductive material adhering to the dielectric surface 4 and having a particular, singular shape, chosen in consideration of the electric, radio or electronic function of the device 2 to which the component 1 is intended to participate. Examples of a component 1 according to the invention are schematically illustrated in FIGS. 1 and 2. The invention also relates as such to an electrical, radio or electronic device 2 comprising such a component 1.

As schematically illustrated in FIGS. 1 and 2, the electro-conductive pattern 5 has a lower surface 5A in contact with the dielectric surface 4 and an opposite upper surface 5B. Advantageously, as schematically illustrated in FIGS. 1 and 2, the upper surface 5B of the electro-conductive pattern 5 is not in contact with said dielectric surface 4, but preferentially extends above said dielectric surface 4. According to a variant illustrated in FIG. 1, the electro-conductive pattern 5 is arranged in direct contact with a surface of the substrate 3. In this case, said substrate 3 is made of a dielectric material, and the surface of the substrate 3 thus forms directly said dielectric surface 4. According to another variant illustrated in FIG. 2, a surface of the substrate 3 is covered with an intermediate coating 6, such as for example a layer of varnish or a layer of primer, forming said dielectric surface 4 provided with said electro-conductive pattern 5. The intermediate coating 6 is therefore made of a dielectric material, and has a lower surface adhering to the surface of the substrate 3 and an opposite upper surface, which thus advantageously forms the dielectric surface 4 carrying the electro-conductive pattern 5. In such a variant, the substrate 3 may possibly not itself be made of dielectric material 4, although it is nevertheless preferable that it is.

Preferably, the substrate 3 is made of a polymer material, a composite or hybrid polymer-matrix material, paper, glass, textile, leather (animal (skin), vegetable or synthetic leather) or ceramic material. It nevertheless remains conceivable, although less preferred, that the substrate 3 is in non-dielectric metal material, in the hypothesis in which the surface of the substrate 3 is covered with an intermediate coating 6, as contemplated hereinabove, which is itself made of a dielectric material so that this intermediate coating 6 forms a dielectric surface 4 in contact with which is placed the electro-conductive pattern 5.

In accordance with the invention, the electro-conductive pattern 5 carried by the substrate 3 is made of metal, i.e. the electro-conductive pattern 5 is thus formed, apart from any non-metallic impurities, of at least one elemental metal (or “elemental simple body”), of at least one mixture of elemental metals, or at least one metal alloy. In other words, the electro-conductive pattern 5 is made of solid metal, and thus forms a continuous metal layer. Moreover, the upper surface 5B of the electro-conductive pattern 5 of the component 1 according to the invention has a roughness Sa that is less than or equal to 500 nm. The “roughness Sa” (or “roughness parameter Sa”) is the extension of the roughness parameter Ra (“roughness Ra” or “Mean Arithmetic Roughness”, relative to a profile) to a surface, so that it thus makes it possible to evaluate, characterize the mean arithmetic roughness of a surface. The “roughness Sa”, and the means and methods for measuring the latter, are defined in particular in the standard ISO 25178:2016. For example, the roughness Sa can be measured using an atomic force microscope, by interferometry or also using a confocal probe. Moreover, the electro-conductive pattern 5 of the component 1 according to the invention has a thickness e that is between 10 nm and 500 nm.

It has been observed that, interestingly, the particular combination of the above-mentioned characteristics in terms of constitution of the electro-conductive pattern 5, roughness Sa of the upper surface 5B and thickness e of the latter provides the component 1 according to the invention with excellent electrical properties in terms in particular of homogeneity of the conductivity/resistivity of the electro-conductive pattern 5. Moreover, the fact that the electro-conductive pattern 5 is made of metal and that the upper surface 5B of the latter has a roughness Sa less than or equal to 500 nm makes it possible to provide the upper surface 5B with a high surface conduction and a particularly smooth finish, which makes it possible to minimize the conduction losses. Moreover, the thinness of the electro-conductive pattern 5 allows the design of a particularly space-saving and easy to integrate component, of particularly low material cost.

In addition to allowing a particularly low thickness e of the electro-conductive pattern 5, the fact that the electro-conductive pattern 5 is made of metal (or “solid metal”), and not in the form of a composite polymer-matrix material in which electro-conductive particles such as for example metal particles are dispersed, as in the case of conventional printed electronics, advantageously provides the electro-conductive pattern 5 with great durability and reliability over time, as its electric conductivity/resistivity properties do not vary significantly over time.

The component 1 according to the invention thus enables in particular the manufacturing of a radio device 2, such as a radio frequency transmitter and/or receiver device, wherein the conductive pattern 5 of the component 1 forms a radio frequency antenna radiating element, having a particularly high quality factor and radiation efficiency, in particular for applications in the High Frequency (HF), Very High Frequency (VHF), Ultra High Frequency (UHF), Super High Frequency (SHF), Extremely High Frequency (EHF) and Terahertz (THz) frequency ranges. The component 1 according to the invention further allows the manufacturing of an electronic device 2 forming a sensor/detector, in which the electro-conductive pattern 5 of the component 1 forms a sensor/detector electrode, having an excellent measurement resolution/sensitivity.

Of course, the invention is not limited to these particular examples of devices 2, and other types of electrical, radio or electronic devices can advantageously benefit from the integration of a component 1 with electro-conductive pattern(s) 5 according to the invention. For example, as will be described hereinafter, the component 1 of the invention can advantageously be integrated into an electrical device 2 in which the electro-conductive pattern 5 forms a heating circuit, to form a particularly efficient electrical heating system.

Even more advantageously, the roughness Sa of the upper surface 5B of the electro-conductive pattern 5 is less than or equal to 300 nm, preferably less than or equal to 200 nm, preferably less than or equal to 100 nm, preferably less than or equal to 50 nm, preferably less than or equal to 20 nm, and still preferably less than or equal to 15 nm. Thus, the level of conduction loss at the upper surface 5B of the electro-conductive pattern 5 is particularly low and well controlled.

Advantageously, the upper surface 5B of the electro-conductive pattern 5 component 1 further has a roughness Ra that is less than or equal to 500 nm, preferably less than or equal to 300 nm, preferably less than or equal to 200 nm, preferably less than or equal to 100 nm, preferably less than or equal to 50 nm, preferably less than or equal to 20 nm, and still preferably less than or equal to 15 nm.

Moreover, it is also advantageous, for the reasons mentioned hereinabove and in particular for radio applications, that the lower surface 5A of the electro-conductive pattern 5 has also a very low roughness. As such, the lower surface 5A of the electro-conductive pattern 5 of the component 1 thus preferably has a roughness Sa that is less than or equal to 500 nm. Still preferably, the roughness Sa of the lower surface 5A of the electro-conductive pattern 5 is less than or equal to 300 nm, preferably less than or equal to 200 nm, preferably less than or equal to 100 nm, preferably less than or equal to 50 nm, preferably less than or equal to 20 nm, and still preferably less than or equal to 15 nm. Advantageously, the lower surface 5A of the electro-conductive pattern 5 component 1 further has a roughness Ra that is less than or equal to 500 nm, preferably less than or equal to 300 nm, preferably less than or equal to 200 nm, preferably less than or equal to 100 nm, preferably less than or equal to 50 nm, preferably less than or equal to 20 nm, and still preferably less than or equal to 15 nm.

Preferably, while being higher than 10 nm, the thickness e of the electro-conductive pattern 5 is less than or equal to 400 nm, preferably less than or equal to 300 nm, and still preferably less than or equal to 200 nm. Such a thinness of the electro-conductive pattern 5 also helps the component 1 to be particularly space-saving and thus easily integrable. It further allows an excellent control of the manufacturing cost, as well as a reduction of the environment impact of the component 1, by limiting the quantity of metal contained in the component 1. Moreover, according to the metal of the electro-conductive pattern 5, such a thinness of the electro-conductive pattern 5 can provide the latter with a certain transparency in the range visible to the human eye.

According to a variant, the thickness e of the electro-conductive pattern(s) 5 is substantially constant according to the extent of the electro-conductive pattern(s) 5, i.e. the thickness e is substantially identical in any point of the electro-conductive pattern(s) 5 (FIGS. 1 and 2). As another variant, the component 1 can have a plurality of electro-conductive patterns 5 whose respective thickness e, substantially constant, is different from one electro-conductive pattern 5 to another. As another variant, the thickness e of the electro-conductive pattern(s) 5 is variable, i.e. the electro-conductive pattern(s) 5 have at least a first area and a second area, distinct from each other, the thickness e of the electro-conductive pattern(s) 5 increasing or on the contrary decreasing (thickness gradient) from said first area to said second area, the value of the roughness Sa of the upper surface 5B of the electro-conductive pattern(s) 5 nevertheless remaining in the above-mentioned ranges of values. Such a difference of thickness e of the electro-conductive pattern(s) 5, in the ranges of values indicated hereinabove, thus advantageously makes it possible to create electro-conductive areas of different conductivity or resistivity, or also different transparency or reflectivity to electromagnetic waves, which can be of particular interest for certain applications of the component 1 and of the electro-conductive pattern(s) 5 comprised by the latter. For example, for a component 1 of the radio device, this can make it possible to create a variation of the wave shielding/reflectivity properties for a metasurface. According to another example, when the electro-conductive pattern(s) 5 form a heating circuit for an electrical heating device, this makes it possible to generate areas of the heating circuit offering different heating intensities when the heating circuit is supplied with electricity.

Advantageously, the metal of the electro-conductive pattern 5 is chosen among the group comprising: silver Ag, nickel Ni, gold Au, copper Cu, aluminium Al, iron Fe and tin Sn, and their alloys. In particular, examples of nickel alloys include nickel-boron Ni—B, nickel-phosphorus Ni—P or nickel-gold Ni—Au alloys. Even more advantageously, said electro-conductive pattern 5 is formed, apart from any non-metallic impurities, of a (single) elemental metal that is silver Ag, considering the excellent intrinsic electrical properties of the latter with respect to other conceivable metals.

Preferably, the metal of the electro-conductive pattern 5 is pure by more than 90%, preferably more than 95%, and still preferably more than 98%. The electro-conductive pattern 5 can thus be advantageously formed of silver Ag, pure by more than 90%, preferably more than 95%, and still preferably more than 98%. Such a level of purity of the metal contributes in particular to the excellent electrical properties of the electro-conductive pattern 5. Moreover, in the case where the component 1 is intended to be used in an electronic device forming a sensor, wherein the electro-conductive pattern 5 forms a sensor electrode, such a level of purity enables to limit the risk of presence of chemical element(s) potentially incompatible with a sensitive sensor element (electronic component, chemical detection substance, etc.) that could be arranged in contact with the electrode formed by the electro-conductive pattern 5. A risk of premature deterioration or ageing of the sensor is thus avoided.

Advantageously, the electro-conductive pattern 5 of the component 1 preferably has an electrical conductivity that is higher than or equal to 25.10⁶ S/m (siemens per metre), preferably higher than or equal to 35.10⁶ S/m, and still preferably higher than or equal to 45.10⁶ S/m.

The electro-conductive pattern 5 of the component 1 advantageously has a sheet resistance (Rs) that is less than or equal to 800 mΩ/□ (ohm per square), preferably less than or equal to 500 mΩ/□ (ohm per square), preferably less than or equal to 300 mΩ/□ (ohm per square), preferably less than or equal to 100 mΩ/□, and preferably less than or equal to 40 mΩ/□. Typically, the sheet resistance Rs can be measured by the four-point method, for example using a 4-point measurement system PRO4 marketed by MICROWORLD®. As known, the 4-point method makes it possible to characterize the resistivity of the thin metal films or layers at ambient temperature. It consists in putting in contact with the surface to be analysed four aligned and equidistant electrodes (or “points”), two of the electrodes being used to inject an electric current of known value between two points of the surface, the two other electrodes being used to measure the potential difference induced. The combination of a low roughness Sa, as mentioned above, of the upper surface 5B of the electro-conductive pattern 5 and of such a preferential value of sheet resistance Rs makes it possible to further limit the conduction losses of the electro-conductive pattern 5, and hence to provide the component 1 with even better performances. In practice, the value of the sheet resistance Rs of the electro-conductive pattern 5 can depend on the thickness e of the electro-conductive pattern 5. Therefore, according to an example, the electro-conductive pattern 5 of the component 1 is formed of silver Ag, pure by more than 90%, preferably more than 95%, and still preferably more than 98%, with a thickness e of 500 nm and a sheet resistance Rs of about 40 mΩ/□. According to another example, the electro-conductive pattern 5 is formed of silver Ag, pure by more than 90%, preferably more than 95%, and still preferably more than 98%, with a thickness e of 50 nm and a sheet resistance Rs of about 800 mΩ/□. Preferably, said at least one electro-conductive pattern 5 has a resolution that is less than or equal to 100 μm, preferably less than or equal to 50 μm, preferably less than or equal to 20 μm, preferably less than or equal to 1 μm. Advantageously, the resolution of the electro-conductive pattern 5 corresponds to a minimum width (e.g. a minimal line width) of the electro-conductive pattern 5 (considered in a plane parallel to a mean plane of extension of the dielectric surface 4) and/or at a minimum distance (or interval) between two electro-conductive patterns 5 or between two parts of a same electro-conductive pattern 5. Such an accuracy of definition of the electro-conductive pattern(s) 5 of the component 1 still improves the electric performances of the latter. In particular, in the case where the electro-conductive pattern 5 of the component 1 forms a radio frequency antenna radiating element, such a resolution makes it possible to obtain a particularly high quality factor, which is favourable to a use of the component 1 in a radio frequency device 2 intended to operate in ranges of radio frequencies from high frequencies (HF) to the Terahertz frequencies (THz). In the case where the electro-conductive pattern 5 of the component 1 forms a sensor electrode, such a resolution of the electro-conductive pattern 5 contributes in particular to an excellent measurement/detection accuracy. In other applications of the component 1, and for example in the case where the electro-conductive pattern(s) 5 form a heating circuit for an electrical heating device 2, the electro-conductive pattern(s) 5 can thus have a particularly small width, limiting the impact of the electro-conductive pattern(s) 5 on the transparency of the substrate 3. Typically, the resolution of the electro-conductive pattern 5 can be measured using a digital microscope, as for example a digital microscope RH-2000 of HIROX®.

Advantageously, according to the considered material and electrical, radio or electronic application, the substrate 3 has a thickness of between 8 μm and 15 mm, and even more advantageously of between 25 μm and 10 mm. As the case may be, the intermediate coating 6 has a thickness of preferentially between 5 nm and 100 μm, and even more preferentially between 15 nm and 20 μm. These dimensional characteristics advantageously helps the component 1 to be particularly space-saving and thus easily integrable, without prejudice for the performances of the latter in terms of electrical conductivity/resistivity.

According to the contemplated applications of the component 1, the substrate 3 (and when applies, the intermediate coating 6) can be transparent (for example, in a range of wavelengths in the visible range for the human eye, and/or in one or more specific electromagnetic wavelength range(s)) or on the contrary opaque. According to the contemplated applications of the component 1, the substrate 3 (and when applies, the intermediate coating 6) can be flexible, i.e. it can advantageously be bent or folded by human force alone, without breaking, deforming or irreversibly deteriorating. Such a flexible nature can advantageously help in the integrability of the component 1. Alternatively, the substrate 3 can on the contrary be substantially rigid, so that it cannot be bent or folded by human force alone without breaking, deforming or irreversibly deteriorating. Such a flexible nature can advantageously help in the robustness of the component 1.

As a variant, the substrate 3 of the component 1, as well as preferably the electro-conductive pattern 5 carried by the latter, preferably have a three-dimensional shape. As used herein, “three-dimensional shape” advantageously means that the substrate 3 and the electro-conductive pattern 5 form, as such, a physical object that expands substantially in the three dimensions of space, along distances that are non-negligible from one another. In other words, the substrate 3 of the component 1, as well as, preferably, the electro-conductive pattern 5, are not flat, i.e. substantially two-dimensional with a very small thickness compared to their other two characteristic dimensions. As such, the substrate 3 is preferably a thermoformed substrate, i.e. its three-dimensional shape results from a step of thermoforming an initially flat thermoformable substrate.

Potentially, the substrate 3 of the component 1 can be over-moulded, typically by injection-moulding of a polymer material or a mixture of polymer materials, in order for example to form a protective and/or support structure of the substrate 3 carrying the electro-conductive pattern 5, which advantageously helps in the mechanical robustness of the component 1.

It is conceivable that the substrate 3, of three-dimensional shape or not, is bonded using any adhesive suitable for a separate piece, which can possibly form a protective and/or support structure of the substrate 3.

Preferably, the component 1 comprises an upper coating that is dielectric (i.e. non-conductive, electrically insulating), which covers at least the upper surface 5B of said at least one electro-conductive pattern 5 carried by the surface 3, so that the electro-conductive pattern 5 so encapsulated between the substrate 3 (or the intermediate coating 6, when applies) and said upper dielectric coating. The presence of such an upper dielectric coating provides the component 1 with a greater robustness and a better reliability, by protecting at least the electro-conductive pattern 5 against the external aggressions, in particular mechanical and/or chemical ones, or against an accidental short-circuit. For example, the upper dielectric coating can be formed of a layer of protective varnish.

Optionally, the component 1 comprises at least one electrical connection element 7 attached to the substrate 3, for example by bonding, soldering or crimping, in electrical contact with the electro-conductive pattern(s) 5, carried by the latter, to electrically connect the electro-conductive pattern(s) 5 of the component 1 to an organ or means, distinct and remote therefrom, suitable for the electrical, radio or electronic application (for example, an electronic radio frequency communication module, an electronic signal processing circuit, a power supply circuit, etc.). It is also conceivable that the component 1 is designed and configured in such a way that the electrical connection between the electro-conductive pattern(s) 5 of said distinct and remote organ or means can be made by direct surface contact with a reconnection using a metal blade connector/EMC joint.

As introduced hereinabove, the invention also relates as such to an electrical, radio or electronic device 2 comprising a component 1 according to the invention, as described hereinabove. It is hence an electrical, radio or electronic device 2 comprising a component 1 comprising a substrate 3 provided with a dielectric surface 4 carrying at least one electro-conductive pattern 5, said electro-conductive pattern 5 having a lower surface 5A in contact with said dielectric surface 4 and an opposite, upper surface 5B, wherein said component 1 is the component 1 in accordance with the above-described one according to the invention. Thus, the description hereinabove of the component 1 according to the invention applies mutatis mutandis to the electrical, radio or electronic device 2 according to the invention.

In practice, and as already mentioned hereinabove, the invention is not particularly limited in terms of nature of electrical, radio or electronic device 2. Nevertheless, several types of electrical, radio or electronic devices 2 that can advantageously benefit from the integration of a component 1 according to the invention have been identified.

In particular, according to an embodiment, the device 2 constitutes a radio device, the electro-conductive pattern 5 of the component 1 forming a radio frequency antenna radiating element, i.e. an antenna part (sometimes simply called “antenna”) capable of transmitting and receiving radio waves.

In accordance with what has been described hereinabove in relation with the component 1 according to the invention, the substrate 3, as well as the electro-conductive pattern(s) 5, of the component 1 of such a radio device 2 can advantageously have a three-dimensional shape, which can make the integration of the component 1 within the radio device 2 easier.

Said radio device 2 can comprise an electronic chip 8, attached to the substrate 3 of the component 1 in electrical contact with the electro-conductive pattern(s) 5 carried by the latter, for example in the case where the radio device 2 constitutes or comprises an RFID tag. Alternatively, the radio device 3 can be devoid of such an electronic chip, but comprise a radio frequency electronic communication module, distinct and remote from the component 1, which is connected to the electro-conductive pattern(s) 5 of the component 1 by means of an electrical connection element 7 attached to the substrate 3 in electrical contact with the electro-conductive pattern(s) 5 and a suitable connection cable 9 connecting the electronic communication module to the electrical connection element 7. For example, the electrical connection element 7 attached to the substrate 3 can be a male or female radio frequency RF connector of the SMA type (“SubMiniature version A”) or a male or female radio frequency RF connector of the U.FL or W.FL type, manufactured by HIROSE®. Potentially, the radio device 2 can further comprise a radio frequency transmitter and/or receiver (not illustrated) designed and configured to remotely interact by radio frequency with the radio frequency antenna radiating element (and/or with the electronic chip 8, as the case may be) of the radio device 2, for establishing a wireless connection for information transmission between the radio device 2 and the radio frequency transmitter and/or receiver.

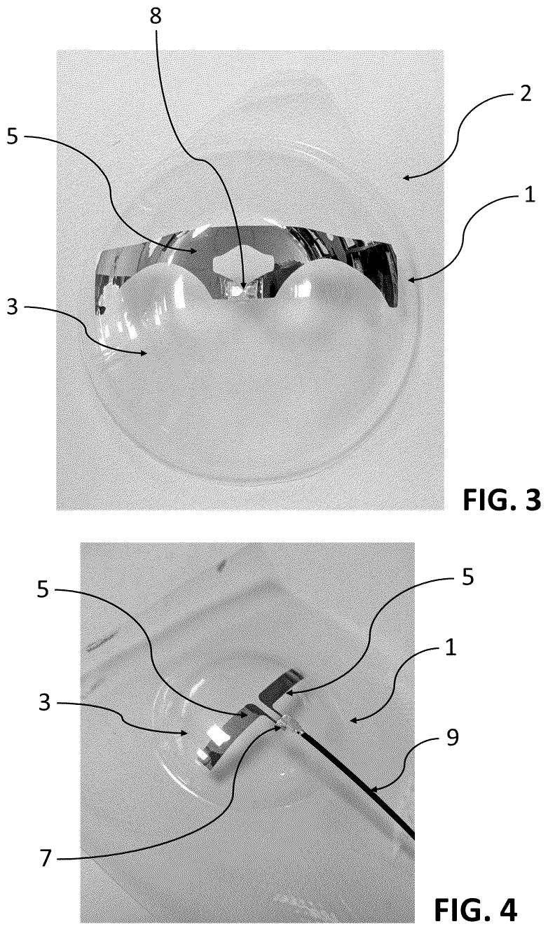

FIG. 3 illustrates in particular a radio device 2 that constitutes a three-dimensional tag for a UHF radio frequency identification (“Radio Frequency IDentification” (RFID)) system, wherein the electro-conductive pattern 5 forms an RFID radio frequency antenna radiating element. The substrate 3 of the component 1 is consisted of a polycarbonate (PC) sheet of initial thickness 250 μm, thermoformed as a semi-sphere (“cup”). The radio device 2 comprises an RFID electronic chip 8, here an RFID Monza R6 chip marketed by IMPINJ®, attached to the substrate 3 using an adhesive, in electrical contact with two adjacent contact areas of the electro-conductive pattern 5. Adhering to the surface of the substrate 3, the electro-conductive pattern 5, made of pure silver Ag, follows the three-dimensional hemispherical shape thereof. The thickness e of the electro-conductive pattern 5 is of about 300 nm. The upper surface 5B of the electro-conductive pattern 5 has a roughness Sa of about 20 nm. The electro-conductive pattern 5 has a sheet resistance Rs of about 85 mOhm/□.

FIG. 4 illustrates an example of component 1 of a radio device 2, whose electro-conductive patterns 5 form a WiFi® (2.4 GHz) dipole radio frequency antenna radiating element, for example for being used in the field of Internet of Things (IoT). Herein, the electro-conductive patterns 5 define two radiative half-strands and a two-wire power supply line. The substrate 3 of the component 1 is consisted of a polycarbonate (PC) sheet of initial thickness 250 μm, thermoformed as a semi-sphere. The thickness e of the electro-conductive patterns 5 is of about 300 nm. The upper surface 5B of the electro-conductive patterns 5 has a roughness Sa of about 20 nm. The electro-conductive patterns 5 have a sheet resistance Rs of about 85 mOhm/□. In order to allow interconnection with a radio frequency electronic communication module (not illustrated), an electrical connection element 7 such as a HIROSE® U.FL RF connector is bonded to the substrate 3 in contact with the two-wire line of the antenna radiating element, using an isotropic conductive glue PANACOL Elecolit® 3661. The end of a suitable radio frequency coaxial cable 9 is connected to the electrical connection element 7, the other end of the cable 9 being intended to be connected to the electronic radio frequency communication module.

According to another embodiment, the device 2 forms a sensor (or detector), as the electronic device 2, said at least one electro-conductive pattern 5 of the component 1 then forming at least one sensor, or detector, electrode. Possibly, a chemical detection substance can be present on part at least of the upper surface 5B of the electro-conductive pattern 5 (chemical sensor). The device 2 can advantageously comprise an adapted electronic measurement circuit connected to the electro-conductive pattern 5.

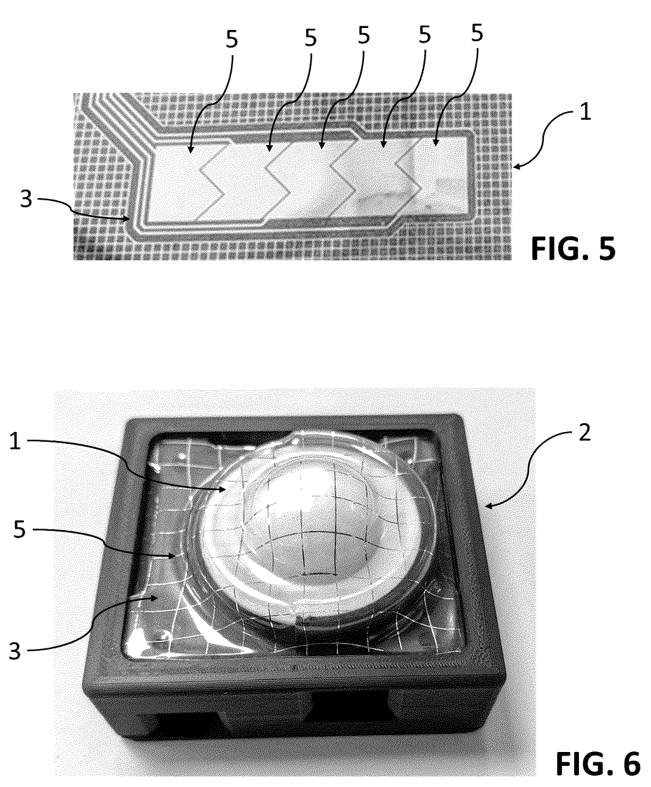

As an example, the electro-conductive pattern 5 can form a capacitive sensor electrode (or “capacitive electrode”), for example to detect, by measuring one of the capacitance of the electro-conductive pattern 5, a contact exerted on the component 1 by a user's finger or the presence of a substance on the component 1 (for example, liquid water or frost). FIG. 5 illustrates an example of such a component 1 whose electro-conductive patterns 5 form capacitive sensor electrodes. In this example, the substrate 3 is consisted of a sheet of polyethylene terephthalate (PET) of initial thickness 125 μm. The electro-conductive patterns 5 are made of pure silver Ag, of thickness e of about 250 nm. The upper surface 5B of the electro-conductive patterns 5 has a roughness Sa of about 20 nm. The electro-conductive patterns 5 have a sheet resistance Rs of about 105 mOhm/□.

According to another example (not illustrated), the electro-conductive pattern(s) 5 can form a resistive sensor electrode (or “resistive electrode”), for example to detect a deformation of the substrate 3 (deformation gauge) by measuring a variation of the electrical resistance between two distinct points (and typically between two opposite ends) of the electro-conductive pattern 5. Moreover, in the case where the substrate 3 is made of a material having a relatively high coefficient of thermal expansion, it can thus be possible to indirectly measure a temperature of the substrate 3. According to still another example (not illustrated), the component 1 can comprise one or more electro-conductive pattern(s) 5 forming two electrodes, between which is arranged a sensitive element whose resistive properties can vary as a function of the environmental conditions (concentration of a particular gas in the surrounding atmosphere, humidity, temperature, etc.).

Moreover, as introduced hereinabove, it has been observed that the component 1 according to the invention can find, in a very interesting manner, an application in an electrical device that is an electrical heating device 2, in which the electro-conductive pattern 5 of the component 1 forms a heating circuit (when an electrical current is applied, typically between two ends of the electro-conductive pattern 5). Typically, the heating circuit (or “resistive circuit”) can take the form of one or more wire(s), one or more grid(s) and/or one or more electro-conductive coil(s). Advantageously, the component 1 can comprise two electrical connection elements 7, for example two omnibus bars, attached to the substrate 3 in electrical contact with the electro-conductive pattern(s) 5. The electrical heating device 2 can advantageously comprise a control and power supply circuit, connected to said electrical connection elements 7.

By way of example, FIG. 6 illustrates an electrical heating device 2 forming a heated/de-icing radome for a radio tracking system (proximity radar sensor), comprising a radar sensor module XM132 manufactured by the ACCONEER company, operating at 60 GHz. The component 1 of the electrical heating device 2 comprises a substrate 3 consisted of a thermoformed polycarbonate (PC) sheet of initial thickness 250 μm. The electro-conductive pattern 5, made of pure silver Ag, forms a grid. To ensure a transparency of the radome to radar waves of the radar sensor module, the grid has meshes of 200 μm width and 5,000 μm aperture. The electro-conductive pattern 5 has a thickness e of 120 nm. The upper surface 5B of the electro-conductive pattern 5 has a roughness Sa of about 20 nm. The electro-conductive pattern 5 has a sheet resistance Rs of about 250 mOhm/□. When the electro-conductive pattern 5 is connected to a DC control and power supply circuit (voltage of about 25 V with a current of about 1.4 A), it is possible to dissipate more than 35 W over a surface of 0.05 m² (i.e. a power higher than 600 W/m²) and to reach a surface temperature of the component 1 of more than 60° C. after 1 min of heating.

Different steps of a method for manufacturing a component 1 according to the invention will now be described by way of illustrative and non-limiting example. According to this method, the metal electro-conductive pattern(s) 5 are manufactured by selective metallization of a previously masked substrate, according to a technique of non-electrolytic chemical deposition of metal on the substrate surface by spraying, in the form of one or more aerosol(s), one or more metallization solution(s) containing at least one metal in metal cation form (oxidizing agent) and at least one reducing agent capable of transforming the metal cation into metal.

This method advantageously allows obtaining in a particularly simple, quick and efficient way a component 1 according to the invention. The examples of component 1 described hereinabove in relation with FIGS. 3 to 6 have been obtained using such a method.

### Step A of Providing a Substrate

Advantageously, the material chosen for the substrate 3 is a dielectric material, preferably a polymer material or a composite polymer-matrix material. To obtain a component 1 whose substrate 3 has a three-dimensional shape, it is preferable that the substrate is initially in a flat shape (flat substrate), with typically a thickness of between 8 μm and 15 mm, and that the material of the substrate 3 is chosen thermoformable. The conceivable thermoformable polymer materials include, by way of non-limiting examples, polystyrene (PS), impact polystyrene (SB/HIPS), polyethylene (PE), polypropylene (PP), polycarbonate (PC), acrylonitrile-butadiene-styrene (ABS), polyvinyl chloride (PVC), polymethyl methacrylate (PMMA), or thermoplastic polyesters, such as polylactic acid (PLA), polyethylene terephthalate (PET) and glycolized polyethylene terephthalate (PETG). To obtain a component 1 whose substrate 3 is substantially flat, the material of the substrate 3 can advantageously be chosen among the thermoformable polymer materials listed hereinabove or among the following examples of thermosetting polymer materials: polyimides, thermosetting polyesters, phenolic resins and epoxies.

Moreover, it is advantageous in terms of ease with which the above-mentioned levels of roughness Sa of the electro-conductive pattern(s) 5 can be obtained, that the substrate 3 chosen has itself an upper surface, intended to carry the electro-conductive pattern(s) 5, with a roughness Sa which is less than or equal to 500 nm, preferably less than or equal to 300 nm, preferably less than or equal to 200 nm, preferably less than or equal to 100 nm, preferably less than or equal to 50 nm, preferably less than or equal to 20 nm, and still preferably less than or equal to 15 nm.

### Potential Step B of Preparing the Substrate Surface

The method can comprise a step B of preparing the substrate surface in order to facilitate implementation and/or to increase efficiency of the following steps of the method. Step B may comprise an operation of cleaning and/or degreasing the substrate surface, by means of any known and suitable product. In addition to or instead of such a cleaning/degreasing operation, step B may comprise an operation of depositing on the substrate surface an intermediate coating 6 made of a dielectric material, such as a layer of varnish, for example a UV cross-linking varnish applied by spraying, by any known and suitable means such as a compressed air spray gun (for example, a High Volume Low Pressure (HVLP) spray gun). In this case, an upper surface of the intermediate coating 6 will form a dielectric surface 4, the substrate 3 will be provided with. The implementation of such an intermediate coating 6 can possibly enable to provide the dielectric surface 4 with a roughness Sa that is less than or equal to 500 nm, preferably less than or equal to 300 nm, preferably less than or equal to 200 nm, preferably less than or equal to 100 nm, preferably less than or equal to 50 nm, preferably less than or equal to 20 nm, and still preferably less than or equal to 15 nm, by “smoothing” the underlying surface of the substrate 3. As an alternative or in complement, step B can comprise a physical and/or chemical treatment for reducing the roughness Sa of the surface of the substrate 3, for example by sandblasting or shot-blasting, to reach the above-mentioned preferential ranges of values.

### Step C of Forming a Temporary Masking Coating

In order to allow a selective metallization of the substrate 3 making it possible to obtain the desired metal electro-conductive pattern(s), the method comprises an operation of forming a temporary masking coating, which adheres to the dielectric surface 4 the substrate 3 is provided with, to obtain a masked substrate having at least one non-masked area, and to thus delimit selectively one or more particular area(s) of the dielectric surface 4 that will carry the electro-conductive pattern(s) 5.

Advantageously, step C is made by selective deposition, or non-selective deposition, then selective removal/elimination, of a layer of a liquid or past masking composition on the dielectric surface 4 of the substrate 3. The deposition of the masking composition may potentially be followed by a drying and/or a curing of the deposited masking composition. According to the formulation of the masking composition chosen, the drying and/or curing of the latter may comprise drying/desolvation, possibly under the effect of a heat input, or polymerization/cross-linking of the deposited masking composition under the effect of a heat input and/or under the action of actinic radiation (e.g., by exposure to ultraviolet (UV) light). The deposition of the masking composition layer may be carried out selectively on the flat substrate surface, by any known and suitable technique of application, and for example screen printing, pad printing, flexography, rotogravure and/or direct printing (e.g. drip or “inkjet”), which makes it possible to achieve a resolution of less than 20 μm for the electro-conductive pattern(s) 5. As an alternative, the formation of the temporary masking coating by photolithography, for example, from said masking composition can allow obtaining resolutions of less than 1 μm, and typically of the order of 100 nm, for the electro-conductive pattern(s) 5.

### Optional Step D of Thermoforming

To obtain a component 1 whose substrate 3 has a three-dimensional shape, it is preferable, as mentioned hereinabove, that the material of the substrate 3 is chosen thermoformable, the substrate 3 being then initially in a flat form (flat substrate). In this case, the method then advantageously comprises a step D of thermoforming the masked substrate obtained at the end of step D of forming a temporary masking coating.

Step D of thermoforming the masked substrate can be advantageously carried out by any known thermoforming means and technique, obviously adapted to the substrate characteristics (nature of the thermoformable material, substrate thickness, etc.) and, as the case may be, to the intrinsic characteristics of the temporary masking coating. Typically, step D is carried out by heating the flat substrate advantageously homogeneously, by conduction and/or by convection and/or by radiation, until the thermoformable material of the substrate is heated at a forming temperature sufficient to render the flat substrate malleable. The forming temperature in question can obviously vary as a function of the thermoformable material chosen. For a thermoformable polymer material, the forming temperature is typically chosen at least equal to a glass transition temperature of the considered material, and nevertheless advantageously below the melting temperature of the material in question. Once made malleable, the flat substrate is pressed against a male (“positive”) or female (“negative”) mould (or counter-form), advantageously with vacuum and/or pressure suction, so that the flat substrate deforms and conforms the mould shape. The deformed substrate is then cooled so that the thermoformable material cures and keeps the shape imparted by the mould, and the deformed substrate is subsequently extracted from the mould.

As the substrate and the temporary masking coating are simultaneously thermoformed (or thermodeformed) during the thermoforming step D, it is advisable that the temporary masking coating is thus itself advantageously thermoformable, or at least thermodeformable, so as to be able to undergo an elongation and thus to follow the deformation of the substrate, while adhering to the surface of the latter, during thermoforming step D. The temporary masking coating is thus advantageously designed, in particular in terms of capacity of elongation/deformation without breaking, to be capable of undergoing the conditions for carrying out step D of thermoforming the substrate, without significant degradation of its function of masking the surface of the latter.

In order to ensure perfect control of the shape of said electro-conductive pattern 5 that is desired to be obtained at the surface of the thermoformed substrate, it is advantageous to provide, before the above-mentioned step C, a step E of defining a two-dimensional masking pattern, along which the temporary masking coating is then formed at the surface of the substrate in said temporary masking coating forming step C, by modelling the deformation of the substrate and of the temporary masking coating, during the thermoforming step D and representing (or modelling) said at least one electro-conductive pattern 5 to be obtained. In other words, a definition of the two-dimensional masking pattern is made by “inverse anamorphosis”, so that this two-dimensional masking pattern, along which the temporary masking coating is formed on the substrate surface in step C, makes it possible to obtain the desired electro-conductive pattern(s) 5 by anticipating and compensating for the effects of the deformation generated by the thermoforming step D. The step of defining such a two-dimensional masking pattern can be carried out using commercially available computer software, such as, for example, the software T-SI/M by SIMCON (formerly CADFLOW), the software PAM-FORM™ by ESI GROUP, the software solution ANAMAP™ by KALLISTO or the software Thermo 3D™ by QUADRAXIS.

### Step F of Increasing the Energy of the Dielectric Surface

The method preferably comprises a step F of increasing the surface energy of the dielectric surface 4 of the substrate 3 to bring said surface energy to a value higher than or equal to 50 or to 55 dynes, preferably higher than or equal to 60 or 65 dynes, or also more preferentially higher than or equal to 70 dynes. This ensures that the substrate is sufficiently wetted for metallisation, and that the resulting metal deposit obtained after metallization and intended to form the electro-conductive pattern(s) 5 adheres sufficiently.

Step F may be carried out before or after step C of forming the temporary masking coating.

The treatment step F for increasing the energy of the substrate surface can be carried out:
by physical treatment, preferably chosen among the following physical treatments: flaming, plasma treatment, corona treatment, and combinations thereof, and/or
by chemical treatment, preferably chosen among the following chemical treatments: application of a silane-based solution, depassivation of the surface using one or more acid solution(s), rare earth oxide polishing, fluorination, acid or alkaline chemical attack to create a microroughness, and the combinations thereof.

More preferentially, the physical treatment is a flaming and/or plasma treatment, in the case in particular in which the substrate, flexible or rigid, is made of a thermoformable polymer material or a composite polymer-matrix thermoformable material. The flaming operation consists, for example, in passing the substrate under a flame whose temperature is for example between 1,200° C. and 1,700° C. The flaming duration is generally of 4 to 50 seconds. The plasma treatment corresponds, for example, to the passage of the substrate to be metallized in a plasma torch. For example, the substrate can be subjected to a so-called “air” plasma: 80% nitrogen/20% oxygen at 0.5 mbar (i.e. 50 Pa) for 2 min. More preferentially, the chemical treatment is a fluorination treatment, in the case in which the substrate, flexible or rigid, is made of a thermoformable polymer material or a composite polymer-matrix thermoformable material. Fluorination corresponds for example to putting the substrate to be metallized into contact, within an enclosure under reduced pressure, with a gaseous solution based on inert gas (argon) containing a fluorine additive.

### Step G of Wetting the Dielectric Surface

The method can comprise, after treatment step F for increasing the surface energy, a step G of wetting the dielectric surface 4, which typically consists in coating the dielectric surface 4 with a liquid film, for example by a spraying or vaporisation/condensation of a wetting liquid, to favour the subsequent spreading of the metallization solution(s) (“redox solution(s)”). The wetting liquid is preferably chosen in the following group: deionised or non-deionised water, optionally with the addition of one or more anionic, cationic or neutral surfactant(s), an alcoholic solution comprising one or more alcohol(s) (for example, isopropanol, ethanol and mixtures thereof), and mixtures thereof. For example, deionised water added with an anionic surfactant and ethanol can be chosen as the wetting solution. The wetting duration depends on the dielectric surface 4 considered and the wetting liquid spraying or vaporisation/condensation rate.

### Step H of Activating/Sensitizing the Dielectric Surface

Within the framework of a metallization by non-electrolytic deposition by spraying one or more metallization solution(s) in the form of aerosols, a previous activation (or at least “sensitization”) step H may be necessary for depositing certain metals. It aims in particular to accelerate the redox metallization reaction. During step H, the substrate surface is put into contact with at least one chemical sensitization species, which is adsorbed on the surface of the substrate 3 and which thereafter accelerates the metallization reaction.

Preferably, the activation step H is carried out after the temporary masking coating forming step C, so that the one or more chemical sensitization species are thus adsorbed both on the temporary masking coating and on the area(s) not masked, i.e. not covered, by the latter.

In practice, step H is preferentially made by spraying onto the substrate surface at least one sensitizing solution, and that by any known and suitable means, such as for example using a compressed air paint gun (e.g., High Volume Low Pressure (HVLP) spray gun). Alternatively, step H could be carried out by immersion of the substrate into at least one sensitizing solution.

For example, a first sensitizing solution based on stannous chloride (SnCl₂) or SnSO₄/H₂SO₄/quinol/alcohol, is applied by spraying or immersion. A palladium or silver-based solution, capable of reacting with ions Sn²⁺ to form nucleation centres at the surface of the substrate, or also a PdSn colloidal solution, formed ex situis then deposited in the same way. For more precision, reference can be made for example to “Metal Finishing Guidebook and Directory Issue”, 1996 Metal Finishing publication, pages 354, 356 and 357. H. Narcus, to “Metallizing of Plastics”, Reinhold Publishing Corporation, 1960, Chapter 2, page 21. F. Lowenheim, or also to “Modern electroplating”, John Wiley & Sons publication, 1974, Chapter 28, page 636. Advantageously, the substrate surface sensitization is implemented using a stannous chloride-based sensitizing solution, for example in accordance with the mode of implementation described in document FR-2 763 962 B1. In this case, a rinsing step using a rinsing liquid is carried out immediately after the sensitization, without intermediate step. As a variant, the substrate 3 surface activation is implemented using a sensitizing solution, for example in accordance with the mode of implementation described in document FR-2 763 962 B1. In this case, a rinsing step using a rinsing liquid as described in the examples hereinafter is carried out immediately after the activation step H, without intermediate step.

### Step I of Non-Electrolytic Chemical Deposition Metallization

The method then comprises a metallization step I for forming a metal deposit intended to form the metal electro-conductive pattern(s) 5, which is carried out by non-electrolytic chemical deposition, using:
either only one metallization solution containing said at least one metal in metal cation form and said at least one reducer adapted to transform the metal cation into metal,
or two distinct solutions: the first solution (“oxidizing solution”) containing at least one metal in metal cation form (oxidizing agent(s)) and the second solution (“reducing solution”) containing one or more reducing agent(s),
or also a plurality of distinct solutions, each able to contain either at least one metal in metal cation form (oxidizing agent(s)), or one or more reducing agent(s), provided that at least one of the solutions (“oxidizing solution”) contains at least one metal in metal cation form and that at least another one of the solutions (“reducing solution”) contains one or more reducing agent(s).

The reducing agent is advantageously chosen strong enough to reduce the metal cation into a metal, i.e. the chosen standard redox potential of the oxidizing/reducing pair of the reducing agent is less than that of the oxidizing/reducing pair of the oxidizing agent (Gamma rule). Such a non-electrolytic variant is in particular advantageous in that it allows the formation, on the surface of a substrate that is indifferently conductive or not, of a solid metal deposit, as contemplated hereinabove, moreover with a thickness advantageously included in the above-mentioned ranges of values.

During the metallization step I, the metallization solution(s) are sprayed in the form of one or more aerosol(s) on the masked substrate, and in particular at least on the unmasked area(s) of the latter. As used herein, “aerosof” means a set of fine particles of the metallization solution(s) in suspension in a gaseous medium (e.g. air). It can therefore advantageously be a mist of droplets smaller than 100 μm, preferably smaller than 60 μm, and more preferentially also from 0.1 μm to 50 μm, obtained by nebulization and/or atomization of the metallization solution(s).

Advantageously, the metallization solution(s) (“redox solutions”) can be obtained from solutions, advantageously aqueous, of one or more oxidizing metal cation(s) (typically obtained by dissolution of one or more corresponding metal salt(s)) and one or more reducing component(s), preferably by dilution of concentrated stock solutions, the diluent being preferably demineralized water. According to the nature of the metal deposit to be formed, the spraying of the metal solution(s) can be carried out continuously, i.e. all at once, or discontinuously by alternating spraying phases and relaxation times. For example, for a silver-based metal deposit, the spraying will be preferentially carried out continuously. For example, for a nickel-based metal deposit, the spraying will be preferentially carried out discontinuously by alternating spraying phases and relaxation times. According to the desired metal deposit thickness, the spraying duration may advantageously vary between 0.5 s and 200 s, preferably between 1 s and 50 s, and even more preferentially between 2 s and 30 s for a substrate surface area to be metallized of 1 dm².

The spraying of the metallization solution(s) can be carried out using any suitable spraying means, preferably using one or more compressed air spray gun(s), such as for example one or more High Volume Low Pressure (HVLP) spray gun(s).

According to the first spraying method, one or more metal cation solution(s) (“oxidizing solution(s)”) and one or more reducing agent solution(s) (“reducing solution(s)”) are sprayed simultaneous and continuously, in the form of one or more aerosol(s), onto the surface to be treated. In this case, the mixture between the oxidizing solution and the reducing solution may be performed just before the formation of the aerosol or also by fusion of an aerosol produced from the oxidizing solution and an aerosol produced from the reducing solution, preferably before they come into contact with the substrate surface. According to the second spraying method, one or more metal cation solution(s) (“oxidizing solution(s)”) then one or more reducing agent solution(s) (“reducing solution(s)”) are sprayed successively, using one or more aerosol(s). In other words, the spraying of the redox solution is carried out through separate, alternating spraying(s) of one or more solution(s) of one or more metal oxidizing agent(s) and one or more solution(s) of one or more reducing agent(s). According to a third spraying method, a metallization solution, made metastable, containing a mixture of said at least one metal in metal cation form (“oxidizing agent(s)”) and said at least one reducing agent are sprayed in aerosol form, then after spraying onto the substrate surface, the metallization solution is activated so as to trigger the transformation of the metallization cation(s) into metal, preferably by contact with a primer, advantageously added using one or more aerosol(s), before, during and after the spraying of the metallization solution. The priming or activation of the redox reaction is then perhaps obtained by any suitable physical (temperature, UV, etc.) or chemical means.

Preferably, water is chosen as a solvent for preparing the metallization solution(s) to be projected as aerosol(s). The concentration(s) in metal salt(s) of the oxidizing solution(s) to be sprayed are preferentially of between 0.1 g/l and 100 g/l and still preferably of between 1 g/l and 60 g/l. As the case may be, the concentration(s) in metal salt(s) of the stock solution(s) are preferably of between 0.5 g/l and 500 g/l, or the dilution factor of the stock solution(s) is preferentially of between 5 and 5,000. Advantageously, according to the nature of the metal of the electro-conductive pattern 5 to be obtained, the metal salts are chosen among silver nitrate, nickel sulphate, copper sulphate, tin chloride, aurochloric acid, iron chloride, cobalt chloride, and mixtures thereof. The selection of the reducing agent(s) is preferably made among the following components: borohydrides, dimethylaminoborane, hydrazine, sodium hypophosphite, formaldehyde, lithium aluminohydride, reducing sugars such as glucose derivatives or sodium erythorbate, and mixtures thereof. The concentration(s) in metal salt(s) of the reducing solution(s) to be sprayed are preferentially of between 0.1 g/l and 100 g/l and still preferably of between 1 g/l and 60 g/l. As the case may be, the concentration(s) in reducing agent(s) of the stock solution(s) are preferably of between 0.5 g/l and 250 g/l, or the dilution factor of the stock solution(s) is preferentially of between 5 and 2,500.

For example, an electro-conductive pattern 5 made of pure silver Ag can be obtained by simultaneous spraying in aerosol form (first spraying method) of the first aqueous metallization solution (oxidizing solution) based on silver nitrate with a concentration of 2 g/l and having a pH>9, and a second metallization solution (reducing solution) based on glucose, for 80 s by means of HVLP guns set at a spraying pressure of less than 2.5 bar (i.e. 2.5.105 Pa).

### Step J of Eliminating the Temporary Masking Coating

The method further comprises a step J of eliminating the temporary masking coating, which aims to remove the temporary masking coating present on the substrate 3, as well as any potential metal deposit that may have formed on the temporary masking coating at the end of the metallization step I, and to thus “reveal” the metal electro-conductive pattern(s) 5.

Advantageously, step J is carried out at least partially by chemical, non-mechanical means, in order to eliminate said temporary masking coating in a simple and clean way, by limiting the risk of degrading the finesse and precision of the electro-conductive pattern(s) 5 to be obtained. Advantageously, temporary masking coating elimination step J is carried out during the metallization step I, or at least partly during step I and after step I, or at least partly during and after step I and partly before step I. As such, temporary masking coating elimination step J comprises at least (or even essentially consists of) one operation of dissolving (at least partially) the temporary masking coating using at least one solvent contained in the metallization solution or one of the metallization solutions implemented during the metallization step I. Herein “dissolving using at least one solvent” means total or partial disintegration, decomposition or loss of cohesion of the temporary masking coating, under the action of a particular fluid (preferably a liquid) chosen for its specific chemically aggressive nature relative to the temporary masking coating, likely to allow it to be disintegrated, detached and evacuated from the substrate surface. It may thus be a mechanism of dissolution into a solvent in the strict chemical sense, but not necessarily.

Preferably, said temporary masking coating is alkali-soluble (or at least alkali-sensitive) so as to be able to be preferentially dissolved by an alkaline solvent contained in the metallization solution or one of the metallization solutions implemented in step I. In practice, the (or one of the) metallization solution(s) chosen has a highly alkaline pH (typically higher than 9), so that the metallization solution(s) can dissolve the temporary masking coating during the metallization step I. For example, during the spraying of the metallization solution(s) in the form of aerosol(s), the unmasked areas of the substrate are metallized, whereas the temporary masking coating is dissolved and evacuated by the effluent, letting appear the desired metal electro-conductive pattern(s).

Step J can possibly comprise, previously to said temporary masking coating dissolution operation, an exposure operation under actinic radiation (e.g., under UV-light) and/or a heat-treatment operation on the temporary masking coating, in order to weaken the temporary masking coating and/or to make the subsequence dissolution thereof easier. Step J may possibly comprise, after such a dissolution operation, an operation consisting in particular in facilitating evacuation of the dissolved temporary masking coating and/or of any debris that is not completely dissolved from the latter, by carrying it along in liquid phase and/or by mechanically carrying it along.

### Steps K and L of Rinsing and Drying the Surface of the Metallized Substrate

After metallization step I, the method preferably comprises a step K of rinsing the surface of the metallized substrate, to evacuate any residue from the temporary masking coating. The rinsing step K may be carried out for example by spraying/projection of one or more rinsing liquid(s) using an HVLP gun or by soaking/immersion into one or more rinsing liquid(s). The latter is preferably water, and still preferably demineralized water, except possibly in the case where the (or one of the) rinsing liquid(s) contains or forms a solvent (other than water) for dissolving the temporary masking coating, to continue, if necessary, the temporary masking coating elimination step J. In particular, after a first rinsing by water spraying, a complementary rinsing can be made by immersion in a bath or by spraying solutions containing a solvent of the ethanol/isopropanol type to guarantee a perfect absence of residues of temporary masking coating and metal deposit carried by these latter.

Step K of rinsing the metal substrate surface can be followed by a step L of drying the metallized substrate surface to evacuate the rinsing liquid. Such a drying may typically be carried out at ambient temperature by blowing a stream of compressed air, for example at a pressure of 5 bar (i.e. 5.105 Pa), or using an air knife-type blowing system.

### Optional Step M of Finishing Treatment of the Metallized Substrate Surface

Advantageously, it may be provided a step M of finishing treatment of the metallized substrate surface consisting in a formation of an upper dielectric coating (protective coating), as contemplated hereinabove, that covers at least the upper surface 5B of said at least one electro-conductive pattern 5 carried by the surface 3. Such a finishing step may be typically realized by deposition/application, by any known and suitable technique, of at least one finishing layer of a curable and/or cross-linkable liquid composition (e.g., by exposure to UV or thermal curing) on the surface of the substrate carrying the electro-conductive pattern(s) 5. The liquid composition can be a paint or a varnish, advantageously chosen for example among the following group: alkyds, polyurethanes, epoxies, vinyls, acrylics and mixtures thereof. Preferably, the liquid composition is a varnish, potentially coloured/pigmented, advantageously chosen among the following compositions: epoxies, alkyds and acrylics.

### Optional Step N of Assembling Additional Elements

Optionally, the method can comprise a step N of assembling to the substrate 3 so provided with one or more metal electro-conductive pattern(s) 5 one or more additional elements, such as an electrical or electronic component, and for example an electronic chip 8 and an electrical connection element 7. Advantageously, such an assembly step N can be implemented using one or more robotised surface-mounted component (SMD) placement systems, commonly known as “pick-and-place” or “P&P” machines, one or more robotised arms. Such an assembly step can advantageously be made by soldering and/or using an electro-conductive adhesive, isotropic or anisotropic, taking for example a film or paste form, and of any suitable chemical nature (silicon, epoxy, acrylic, etc.). If necessary, the electro-conductive adhesive can be cured.

### POSSIBILITIES OF INDUSTRIAL APPLICATION

The invention finds its application in the field of design and manufacture of components for electrical, radio or electronic devices, such as in particular for radio frequency transmitter and/or receiver radio devices or for sensors/detectors, comprising a substrate provided with a dielectric surface carrying at least one electro-conductive pattern.

1. A component (1) for an electrical, radio or electronic device (2), comprising a substrate (3) provided with a dielectric surface (4) carrying at least one electro-conductive pattern (5), said electro-conductive pattern (5) having a lower surface (5A) in contact with said dielectric surface (4) and an opposite upper surface (5B), said component (1) being characterized in that said electro-conductive pattern (5) is made of metal, the upper surface (5B) of the electro-conductive pattern (5) having a roughness Sa less than or equal to 500 nm, said electro-conductive pattern (5) having a thickness (e) of between 10 nm and 500 nm and a sheet resistance that is less than or equal to 800 mΩ/□.

2. The component (1) according to claim 1, characterized in that the roughness Sa of the upper surface (5B) of the electro-conductive pattern (5) is less than or equal to 300 nm, preferably less than or equal to 200 nm, preferably less than or equal to 100 nm, preferably less than or equal to 50 nm, preferably less than or equal to 20 nm, and still preferably less than or equal to 15 nm.

3. The component (1) according to claim 1, characterized in that the lower surface (5A) of the electro-conductive pattern (5) has a roughness Sa that is less than or equal to 500 nm.

4. The component (1) according to claim 3, characterized in that the roughness Sa of the lower surface (5A) of the electro-conductive pattern (5) is less than or equal to 300 nm, preferably less than or equal to 200 nm, preferably less than or equal to 100 nm, preferably less than or equal to 50 nm, preferably less than or equal to 20 nm, and still preferably less than or equal to 15 nm.

5. The component (1) according to claim 1, characterized in that the thickness (e) of the electro-conductive pattern (5) is less than or equal to 400 nm, preferably less than or equal to 300 nm, and still preferably less than or equal to 200 nm.

6. The component (1) according to claim 1, characterized in that said metal is chosen among the group comprising: silver Ag, nickel Ni, gold Au, copper Cu, aluminium Al, iron Fe and tin Sn, and their alloys.

7. The component (1) according to claim 6, characterized in that said electro-conductive pattern (5) is formed of an elemental metal that is silver Ag.

8. The component (1) according to claim 1, characterized in that the metal of the electro-conductive pattern (5) is pure by more than 90%, preferably more than 95%, and still preferably more than 98%.

9. The component (1) according to claim 1, characterized in that the electro-conductive pattern (5) has a sheet resistance that is less than or equal to 100 mΩ/□, and still preferably less than or equal to 40 mΩ/□.

10. The component (1) according to claim 1, characterized in that said electro-conductive pattern (5) has a resolution that is less than or equal to 100 μm, preferably less than or equal to 20 μm, preferably less than or equal to 1 μm.

11. The component (1) according to claim 1, characterized in that it comprises at least one electrical connection element (7) attached to the substrate (3) in electrical contact with said electro-conductive pattern (5).

12. The component (1) according to claim 1, characterized in that the substrate (3) is made of a polymer material, a composite polymer-matrix material, paper, glass, textile, leather or ceramic material.

13. The component (1) according to claim 1, characterized in that a surface of the substrate (3) is covered with an intermediate coating (6) forming said dielectric surface (4) provided with said electro-conductive pattern (5).

14. The component (1) according to claim 1, characterized in that said substrate (3) and said electro-conductive pattern (5) have a three-dimensional shape, said substrate (3) being preferably a thermoformed substrate.

15. An electrical, radio or electronic device (2) comprising a component (1) according to claim 1.

16. The device (2) according to claim 15, characterized in that it constitutes a radio device, the electro-conductive pattern (5) forming a radio frequency antenna radiating element.

17. The device (2) according to claim 15, characterized in that it constitutes a sensor, said electro-conductive pattern (5) forming a sensor electrode, for example capacitive or resistive sensor electrode.
